(19) United States
(12) Patent Application Publication
(10) Pub. No.: US 2023/0143088 A1
(43) Pub. Date: May 11, 2023

(54) PLANAR ANTENNA BOARD

(71) Applicant: MEIKO ELECTRONICS CO., LTD., Ayase-shi Kanagawa (JP)

(72) Inventors: Mitsuaki TODA, Ayase-shi, Kanagawa (JP); Kanemitsu NAGAI, Ayase-shi, Kanagawa (JP); Mitsuo IWAMOTO, Ayase-shi, Kanagawa (JP)

(21) Appl. No.: 17/904,951

(22) PCT Filed: Mar. 24, 2020
(86) PCT No.: PCT/JP2020/012994

§ 371 Date: Aug. 24, 2022

(51) Int. Cl. H01Q 9/04; H01Q 1/48

(52) U.S. Cl. CPC H01Q 9/0407; H01Q 1/48

(57) ABSTRACT

A planar antenna board (1) comprises a dielectric (2), an antenna layer (3) formed as a conductor for a signal line on one surface of the dielectric (2), and a ground layer (4) formed as a ground conductor on the other surface of the dielectric (2). The dielectric (2) has: a low-dielectric layer (2a) arranged on the antenna-layer (3) side; an intermediate layer (2b) for which the dielectric constant is higher than that of the low-dielectric layer (2a); and an adhesive layer (2c) for which the glass transition point is higher than that of the intermediate layer (2b), and the water absorption rate is higher than that of the low-dielectric layer (2a). The low-dielectric layer (2a) is arranged on the antenna-layer (3) side with respect to the intermediate layer (2b), and the adhesive layer (2c) is arranged on the ground-layer (4) side with respect to the intermediate layer (2b).

### TECHNICAL FIELD

The present invention relates to a planar antenna board, which is mainly applied to a micro strip antenna (patch antenna).

### BACKGROUND ART

Recently, high speed is required in data communication (for example, data transmission in houses and movie data downloading outdoors). As a solution for realizing such high speed communication, the use of extremely high frequency (20 GHz to 300 GHz) is anticipated. There are various types of antennas that can handle the extremely high frequency. Among those, micro strip antennas, which are simple in structure and low cost in production, are attracting attention. Especially, microstrip antennas can easily be formed by etching patterns in conductive film on an insulative board. So, microstrip antennas are able to contribute to downsizing and price reduction.

Planar antenna boards represented by the microstrip antenna are configured with, a dielectric as an insulating layer, an antenna layer (positive side) formed as a conductor for a signal line on one side of the dielectric, and a ground layer (negative side) formed as an earth conductor on the other side of the dielectric. The ground layer is also called “ground conductor plate” or “ground plate”.

In the planar antenna board with such a configuration, the dielectric and the ground layer are bonded with adhesive (Refer to patent document 1 for example). The patent document 1 is directed to the invention, in which a void is prevented by a bonding process. In the patent document 1, the thickness of the dielectric is 0.1 mm or more and 2.0 mm or less.

As a dielectric, a low-dielectric material must be used so as to be compatible with the extremely high frequency as discussed above. This is because the frequency to be handled is so high that increase of dielectric loss is concerned and high frequency property is required. As a result, in many cases, LCP (liquid crystal polymer) or PTFE (polytetrafluoroethylene) having such properties, or glass cloth or high-polymer material provided with low-dielectric properties are used for this type of dielectric.

### PRIOR ART DOCUMENT

### Patent Literature

Patent document 1: Japanese Patent Application Publication 2019-216299

### SUMMARY OF INVENTION

### Technical Problem

When the dielectric is formed with the aforementioned materials having low-dielectric properties, the thickness in general needs to be within the range between 0.1 mm or more and 0.5 mm or less. Otherwise, the production cost will be extremely high. However the thickness in this range will be too thin for the dielectric to maintain adequate rigidity. Then, handling of circuit formation is difficult and possibility of creating warpage is high, so that a void is likely to be created in the bonding process. This problem also causes the increase of assembly cost. Considering the rigidity aspect, the dielectric preferably has about 1.6 mm thickness. However, as mentioned above, creating the thickness over 0.5 mm is not realistic in terms of cost. Therefore, the dielectric having a thickness of 0.1 mm or more and 2.0 mm or less as shown in patent document 1 is not realistic in terms of cost when the dielectric is formed with low-dielectric material.

Also, the material, having the low-dielectric properties mentioned above, is in the film shape, and therefore has a high gas barrier property and an extremely low water absorption property. Therefore, even if adhesive is used for bonding with a ground layer, a degree of adhesion is not so high because a dielectric repels water.

This invention is made in consideration of the above-mentioned conventional technique and aimed at providing a planar antenna board that can obtain ideal strength (rigidity) even when the material having a low-dielectric property compatible with extremely high frequency is used as a dielectric and that can increase bonding performance with a ground layer.

### Solution to Problem

In order to achieve the aforementioned purpose, the present invention provides a planar antenna board comprising a dielectric, an antenna layer formed as a conductor for a signal line on one side of the dielectric, and a ground layer formed as a ground conductor on another side of the dielectric, wherein the dielectric includes: a low-dielectric layer arranged on a side of the antenna layer; an intermediate layer that has higher permittivity than the low-dielectric layer; and a bonding layer that has higher glass transition point than the intermediate layer and has higher water absorption coefficient than the low-dielectric layer. The low-dielectric layer is arranged on the side of the antenna layer in relation to the intermediate layer, and the bonding layer is arranged on a side of the ground layer in relation to the intermediate layer.

Preferably, the bonding layer and the ground layer are in direct contact with each other.

### Advantageous Effects of Invention

According to the present invention, the dielectric has a three-layer structure. So even when the material having low-dielectric properties to be able to handle extremely high frequency is used, low-dielectric layer can only be made with thickness that exhibits antenna properties, and the other layers (an intermediate layer and a bonding layer) can be made with materials that can form relative thickness. Therefore, the thickness of 0.6 mm or more and 2.0 mm or less, which is said to be preferably 1.6 mm, can be formed at low cost and with a sufficient rigidity needed for a dielectric. Therefore, the dielectric can obtain sufficient thickness and rigidity, but the thickness per layer constituting the dielectric is not so thick. So, it is easy to manufacture. Moreover, if the layers other than the low-dielectric layer are separated into the intermediate layer and the bonding layer, a bonding area can be formed with a material that has high adhesion performance, and the adhesion with the ground layer can also be enhanced.

Also, by employing the structure, in which the bonding layer and the ground layer are in the direct contact with each other, adhesive will be unnecessary. As a result, the structure is simplified and productivity is enhanced.

### BRIEF DESCRIPTION OF DRAWINGS

FIG. 1 is a schematic cross sectional view of a planar antenna board according to the present invention.

FIG. 2 is a schematic cross sectional view of another planar antenna board according to the present invention.

FIG. 3 is a schematic cross sectional view of yet another planar antenna board according to the present invention.

### DESCRIPTION OF EMBODIMENTS

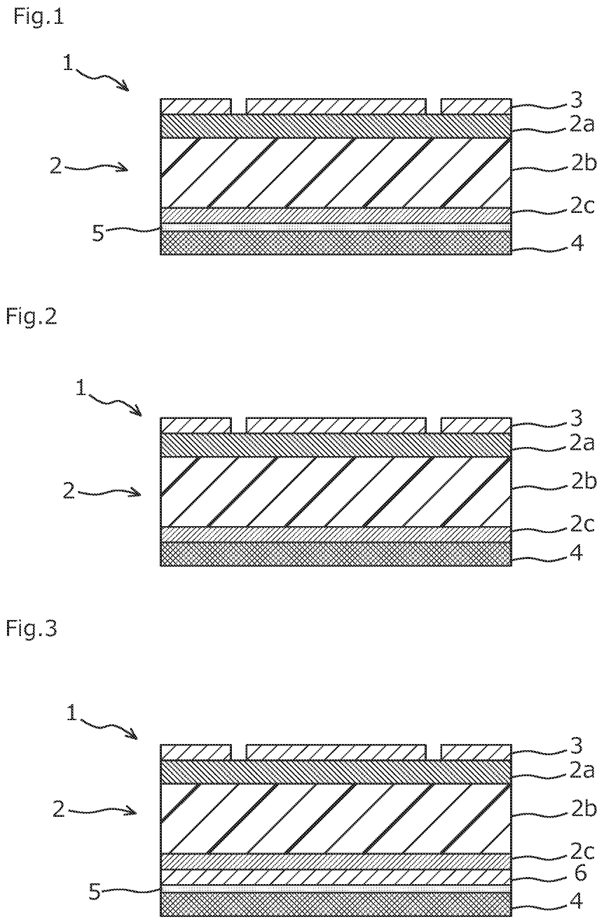

As shown in FIG. 1, the planar antenna board 1 according to the present invention includes a dielectric 2 formed with an insulation material. On one side of the dielectric 2, an antenna layer 3 formed as a conductor for a signal line is arranged. The antenna layer 3 is formed as a print pattern in the production of a printed wiring board, for example. On the other side of the dielectric 2, a ground layer 4 formed as a ground conductor is arranged. Specifically, the dielectric 2 and the ground layer 4 are bonded via an adhesive 5. Although not shown in the drawings, the power supply to the antenna layer 3 is usually conducted from the ground layer 4 side. As a ground layer 4, a plate made of aluminum or glass fiber is used.

The dielectric 2 has a three-layer structure, and is formed as, from the antenna layer 3 side, a low-dielectric layer 2a, an intermediate layer 2b, and a bonding layer 2c. That is, the low-dielectric layer 2a is arranged on the antenna layer 3 side with respect to the intermediate layer 2b, and the bonding layer 2c is arranged on the ground layer 4 side with respect to the intermediate layer 2b. As such, the dielectric is in the three-layer structure. Therefore, each layer can be formed thin while the sufficient rigidity of the thickness of the dielectric 2 as a whole is maintained.

Here, the low-dielectric layer 2a is formed with a material that has lower permittivity than the intermediate layer 2b. In other words, the intermediate layer 2b has higher permittivity than the low-dielectric layer 2a. LCP, PTFE, or FR-4 (epoxy resin material) having low-dielectric properties is used as a low-dielectric layer 2a. For example, the permittivity of LCP is 3.0, and the permittivity of PTFE is 2.2 or more and 3.0 or less, and the permittivity of FR-4 having low-dielectric properties is 3.0 or more and 4.0 or less. These low-dielectric materials all have the permittivity of the same value, and therefore not be used for the intermediate layer 2b. As the intermediate layer 2b, a generally available FR-4, which has definitely higher permittivity than these low-dielectric materials, is used. The permittivity of the generally available FR-4 is 4.0 or more and 5.5 or less. Incidentally, it is said that the permittivity compatible with the extremely high frequency is 3.5 or less. Therefore, the materials to be used for the low-dielectric layer 2a are not limited to the above mentioned low-dielectric materials, but any materials can be used as long as it has the permittivity lower than 3.5.

As described above, forming over 5 mm thickness of low-dielectric material is costly, so it is difficult to form the thickness having sufficient rigidity. However, according to the present invention, the dielectric 2 is formed in three-layer structure. Thereby, even when the material having low-dielectric property is used to be able to handle the extremely high frequency, the low-dielectric layer 2a can only be formed with a thickness that can exhibit antenna property. And other layers (intermediate layer 2b and the bonding layer 2c) can be formed with a material that can form relative thickness. Therefore, the thickness of the dielectric 2 between 0.6 mm or more and 2.0 mm or less, which is preferably about 1.6 mm, can be provided with a sufficient rigidity and can be produced at a reduced cost. Therefore, the dielectric 2 can be given with sufficient thickness and rigidity. But the thickness per layer constituting the dielectric 2 can be not so thick, therefore the production can be performed easily. Incidentally, the actual thickness of the low-dielectric 2a is determined based on the antenna characteristics and the pattern forms of the antenna layer 3.

For the bonding layer 2c, a material, which has higher glass transition point (Tg) than the intermediate layer 2b and higher water absorption coefficient than the low-dielectric layer 2a, is used. For example, the FR-4, which is provided with high glass transition point properties, is used. The glass transition point of generally available FR-4 mentioned above is 150° C. or lower, so the FR-4 to be used for the bonding layer 2c should have the glass transition point higher than that. Furthermore, the bonding layer 2c requires high water absorption coefficient. With regard to this point, the bonding layer 2c requires the water absorption coefficient higher than the low-dielectric layer 2a. The water absorption coefficient of LCP is 0.04% (50° C./48 h), and the water absorption coefficient of FR-4 having low-dielectric properties is 0.14% (25° C./50 h). So, the bonding layer 2c requires water absorption coefficient higher than these. The FR-4, which is provided with high glass transition point properties, has higher water absorption coefficient than these, so the FR-4 is preferably used. As described above, other than the low-dielectric layer 2a is separated into the intermediate layer 2b and the bonding layer 2c, and the side to which the ground layer 4 is bonded is made as the bonding layer 2 formed with the high adhesion performance material. Thereby, the adhesion performance between the dielectric 2 and the ground layer 4 can be enhanced.

Preferably, in terms of production cost, the thickness of the low-dielectric layer 2a is 0.1 mm or more and 0.5 mm or less, and the thickness of the bonding layer 2c is 0.06 mm or more and 0.2 mm or less, which is the thickness that exhibits sufficient adhesion performance. The intermediate layer 2b is provided mainly for enhancing rigidity, and formed to have a thickness, which is calculated by subtracting the thickness of the low-dielectric layer 2a and the thickness of the bonding layer 2c from the thickness of the dielectric 2 required as a whole. In general, the FR-4 of about 1.5 mm can easily form the thickness. So, the total thickness of about 1.6 mm can easily be formed without much cost. As described above, the three layers that form the dielectric 2 are each formed with different material. In this way, the planar antenna board 1, which is capable of handling the extremely high frequency while having sufficient rigidity can be obtained.

Here, as clearly shown in FIG. 2, the ground layer 4 and the dielectric 2 do not have to be bonded via the adhesive 5. The ground layer 4 may be brought into direct contact to the bonding layer 2c by using the adhesion performance of the ground layer 2c. As described above, in the structure where the bonding layer 2c and the ground layer 4 are direct contact to each other, the adhesive 5 will be unnecessary. Accordingly, the structure can be simplified and the productivity can be enhanced.

As shown in FIG. 3, copper foil 6 may be provided on the bonding layer 2c side, and the copper foil 6 and the ground layer 4 may be bonded via the adhesive 5. In this way, the planar antenna board 1 of the present invention is highly versatile since it can be applied to any antenna structure as long as it has the three-layer structure as the dielectric 2.

### DESCRIPTION OF REFERENCE NUMERALS

1: planar antenna board, 2: dielectric, 2a: low-dielectric layer, 2b: intermediate layer, 2c: bonding layer, 3: antenna layer, 4: ground layer, 5: adhesive, 6: copper foil

1. A planar antenna board comprising: a dielectric;
an antenna layer, which is formed as a conductor for a signal line on one side of the dielectric; and
a ground layer formed as a ground conductor on another side of the dielectric, wherein
the dielectric includes: a low-dielectric layer arranged on a side of the antenna layer; an intermediate layer that has higher permittivity than the low-dielectric layer; and a bonding layer that has higher glass transition point than the intermediate layer and has higher water absorption coefficient than the low-dielectric layer;
the low-dielectric layer is arranged on the side of the antenna layer in relation to the intermediate layer; and
the bonding layer is arranged on a side of the ground layer in relation to the intermediate layer.

2. The planar antenna board according to claim 1, wherein the bonding layer and the ground layer are in direct contact to each other.
